(19) United States
(12) Patent Application Publication
(10) Pub. No.: US 2022/0155103 A1
(43) Pub. Date: May 19, 2022

(54) MICROSYSTEM AND METHOD FOR PRODUCING THE SAME

(71) Applicant: Fraunhofer-Gesellschaft zur Förderung der angewandten Forschung e.V., Munchen (DE)

(72) Inventors: Thomas LISEC, Itzehoe (DE); Malte Florian NIEKIEL, Itzehoe (DE); Shanshan GU-STOPPEL, Itzehoe (DE); Fabian LOFINK, Itzehoe (DE)

(21) Appl. No.: 17/665,805

(22) Filed: Feb. 7, 2022

Related U.S. Application Data
(63) Continuation of application No. PCT/EP2020/072267, filed on Aug. 7, 2020.

(30) Foreign Application Priority Data
Aug. 13, 2019 (DE) 10 2019 212 091.1

(51) Int. Cl. G01D 5/14; G01D 5/16

(52) U.S. Cl. CPC G01D 5/145; G01D 5/16

(57) ABSTRACT

A microsystem has a first support element and a second support element, wherein a relative position of the first support element and the second support element among each other is variable. The microsystem has a permanent-magnetic unit connected to the first support element in a mechanically fixed manner and configured to generate a magnetic field. Additionally, the microsystem has a sensor unit connected to the second support element in a mechanically fixed manner and configured to detect the magnetic field and provide a sensor signal which is based on the magnetic field. The sensor signal indicates a relative position of the support elements among one another.

### CROSS-REFERENCE TO RELATED APPLICATIONS

This application is a continuation of copending International Application No. PCT/EP2020/072267, filed Aug. 7, 2020, which is incorporated herein by reference in its entirety, and additionally claims priority from German Application No. 10 2019 212 091.1, filed Aug. 13, 2019, which is also incorporated herein by reference in its entirety.

### BACKGROUND OF THE INVENTION

The present invention relates to a microsystem and to a method for producing the same, wherein particularly microsystems comprising a permanent-magnetic element are described. Additionally, the present invention relates to magnetic position detection for MEMS.

In many MEMS (micro-electro-mechanical system) applications, it is necessary to precisely monitor the position of the movable microstructure, for example as a control signal in closed loops. In particular, capacitive, piezoresistive or piezoelectric sensor elements which can be integrated in the MEMS component are used here. However, monitoring large travel distances and tilting in the narrowest space is only possible to a limited extent. Magnetic position detection based on observing the magnetic field of a permanent magnet mounted to the movable structure is an alternative. There are solutions which are based on using hybrid-mounted conventional miniature magnets. However, these are not suitable for mass applications.

A frequently used technique is capacitive position detection using planar or comb-like electrode pairs, wherein one of the electrodes is arranged at the movable element, as is illustrated schematically in FIG. 14a and FIG. 14b. FIG. 14a shows a three-dimensionally movable platform (3D stage) 1002 which is movable relative to a counter electrode or ground electrode 1004 and can be driven by means of actuators 1006₁-1006₄. FIG. 14b, in contrast, shows an MEMS scanner in which a micromirror 1008 can be deflected via torsion beams 1012 and comb electrodes 1014₁. This means that FIGS. 14a and 14b show examples of MEMS elements having electrostatic drive and capacitive position detection while using interdigitating structures (comb electrodes, comb-drive actuators). The main advantages are easy integration in MEMS elements due to the manufacturing processes available and the availability of integrated circuits which allow resolutions in the range of a few fF (femtofarads). However, capacitive position detection is suitable only for very small travel distances since the capacity is proportional to the inverse of the electrode distance and consequently decreases very quickly with an increasing electrode distance in the simple parallel plate configuration. Using comb structures which keep the electrode distance constant offers an improvement. The capacitive signal in this case is directly proportional to the overlap of the comb areas. Due to the entailed precision in manufacturing, the comb structures manufacturable are highly restricted from a geometrical point of view, which in turn means a limitation of the monitorable travel distances. In the 3D stage in accordance with FIG. 14a, as is described, for example, in [1], the values are 12.5 μm in the x and y directions and 3.5 μm in the z direction, for example. In the MEMS scanner in accordance with FIG. 14b, which is described in [2], a (mechanical) tilting angle of up to 20° is monitored. Only very few of the applications of capacitive position detection are inertial sensors and MEMS scanners.

Piezoresistive position detection is an alternative. When compared to capacitive detection, larger travel distances can be monitored. However, integrating piezoresistors in MEMS devices entails considerably more complexity when compared to the electrodes used for capacitive detection. Additionally, four resistors are connected to form a Wheatstone measuring bridge, to increase the sensitivity, which results in increased space requirements. For an MEMS scanner, which is described in [3], for example, and which allows position detection in the x/y plane, a total of 16 piezoresistors are used, for example.

An essential disadvantage of capacitive and piezoresistive position detection is that signal detection cannot be performed in a contact-free manner, but electrical and mechanical connections to the sensor elements are used, i.e. special elastic structures within the MEMS device are used. The elastic structures used become larger with an increasing travel distance in order to allow corresponding deformation. In addition, in both cases, the result is mechanical coupling to the drive. In the case of piezoresistive position detection, additionally a force is used to deform the piezoresistive elements. In capacitive position detection, the force to be overcome results from electrostatic interaction.

Consequently, contact-free optical position detection, which is widespread in industrial application, is of interest for MEMS. In [4], optical position detection is, for example, used to implement a sensor for magnetic fields. Cheap and miniaturizable systems, however, entail that the light source and PSD (position sensing device) be integrable into the MEMS device. Example of this are, for example, shown in [5].

Magnetic position detection is another contact-free technique. A classical application is precision travel measurement or precision position determining in machine tools, for example. Position detection here is performed pursuant to the encoder principle, i.e. using a comparison between a predetermined pattern and a measured waveform. A magnetic linear scale and one or more magnetic field sensors which move back and forth in a small distance, as is described, for example, in FIG. 15a or in [6], are used here. A system for magnetic position detection illustrated schematically in FIG. 15a comprises a magnet scale or magnetic scale 1016 in order to generate magnetic field lines 1018 which are detected by means of a magnetoresistive (MR) sensor 1022 to provide analog signals 1024 to evaluating electronics 1028 via a connective line 1026. The classical scale here mostly consists of a hard-magnetic ferrite band mounted on a support made of stainless steel. A positioning precision of 0.5 μm can be achieved using modern MR sensors and optimized measuring algorithms. Additionally, there are applications in which the magnetic position detection is not performed pursuant to the encoder principle, but using the absolute values measured. Frequently, the requirements to precision are smaller, like in magnetic switches for detecting open or closed doors or windows or sensors for detecting the filling level in close containers, for example. Tactile sensors for robotics are also worth mentioning, as are illustrated in FIG. 15b and described in [7]. A magnet 1032 is enclosed by an elastomer 1034 and generates a magnetic field 1036 detected by a 3D Hall sensor 1038. The Hall sensor 1038 can be arranged on a rigid or solid substrate 1042.

Magnetic position detection has hardly played a role for MEMS. The main problem is the lack of suitable micromagnets which are able to generate strong magnetic fields over large distances and can be integrated into an MEMS element on the substrate plane. Apart from the material, the characteristics are particularly dependent on the dimensions of the magnet. The gradient at which the field of a magnet decreases will be the steeper the smaller the magnet, but the absolute value of the flux density also decreases with smaller magnets. The aspect ratio of the magnet, i.e. the ratio between length (or height) of the magnet and its diameter (or surface area) has an important role here. High aspect ratios allow using small diameters while ensuring a constant flux density. Magnets having a diameter of more than 50 μm and an aspect ratio of at least 3:1 would be well suitable for MEMS. However, with magnets of diameters (edge lengths) of greater than 500 μm, smaller aspect ratios are also acceptable. However, the depositing processes of semiconductor technology are designed only for layers of a few micrometers. The volume of magnets produced in this way remains far below the region aimed at. Structures having a thickness of some ten micrometers can be deposited galvanically. However, the corresponding processes are available only for certain magnetic materials. In [8], a linear scale having a particularly fine pole structure for measuring systems in accordance with FIG. 15a is produced on an Si substrate by means of CoNiP galvanic processes. [9] describes an MEMS switch which is based on a movable microstructure made of galvanically deposited FeNi, which is actuated by a magnetic field. Magnetic high-performance materials, like NdFeB or SmCo, cannot be deposited galvanically. Aspect ratios of greater than 1:1 cannot be achieved for structures having a diameter or edge length of 50 μm. Depositing NdFeB layers having a thickness of more than 100 μm by means of Pulsed Laser Deposition (PLD) is shown in [10]. However, microstructuring of such layers remains unsolved in these manufacturing processes. Alternatively, NdFeB micromagnets can be produced by means of dispersing solutions containing magnets, [11], however, the shape and dimensions thereof vary dramatically. Filling microforms in an Si substrate with loose magnetic powder and subsequently fixing the same, for example by coating the substrate using parylene, is an alternative [12]. Due to the limited thermal stability of organic materials and the insufficient protection of magnetic particles from corrosion, further processing of such substrates is restricted considerably.

Microsystems allowing precise position monitoring of large travel distances, which are precise and easy to manufacture, would be desirable.

The object underlying the present invention is providing a microsystem and a method for producing a microsystem, which allow precise and easy manufacturing and allow precise position monitoring of large travel distances in future operation.

### SUMMARY

According to an embodiment, a microsystem may have: a first support element and a second support element, wherein a relative position of the first support element and the second support element relative to each other is variable; a permanent-magnetic means connected to the first support element in a mechanically fixed manner and configured to generate a magnetic field; a sensor means connected to the second support element in a mechanically fixed manner and configured to detect the magnetic field and to provide a sensor signal which is based on the magnetic field; wherein the sensor signal indicates the relative position of the support elements relative to each other.

According to another embodiment, a method for producing a microsystem may have the steps of: connecting a permanent-magnetic means configured to generate a magnetic field, to the first support element in a mechanically fixed manner; connecting a sensor means configured to detect the magnetic field and provide a sensor signal which is based on the magnetic field, to the second support element in a mechanically fixed manner; arranging a first support element and a second support element such that a relative position of the first support element and of the second support element among each other is variable; so that the sensor signal indicates the relative position of the support elements among one another.

A core idea of the present invention is connecting a permanent-magnetic means to a support element of a microsystem in a mechanically fixed manner, which can be done easily and precisely. This allows precise position monitoring of large travel distances.

In accordance with an aspect of the present invention, the permanent-magnetic means is provided by an agglomeration of magnetic particles. The magnetic particles may, for example, be connected to form a fixed (or rigid or solid) structure by means of atomic layer deposition, wherein the solid structure can at the same time be connected to the support element in a mechanically fixed manner using the coating. Regions or cavities can be manufactured precisely in the support substrates, thus allowing a volume filled by particles to be adjustable precisely, and thus also a volume having a permanent-magnetic means to be adjustable precisely, as well as a geometry and an aspect ratio. Subsequent atomic layer deposition on filled magnetic particles allows precisely introducing magnetic structures into support elements in an easy and reproducible manner, or arranging the same thereon.

In accordance with an embodiment, a method for producing a microsystem comprises arranging a first support element and a second support element such that a relative position of the first support element and the second support element among each other is variable. The method comprises connecting a magnetic means configured to generate a magnetic field, to the first support element in a mechanically fixed manner. The method comprises connecting a sensor means configured to detect the magnetic field and provide a sensor signal which is based on the magnetic field. The sensor means is connected to the second support element in a mechanically fixed manner. The method is performed such that the sensor signal indicates the relative position of the support elements among one another.

### BRIEF DESCRIPTION OF THE DRAWINGS

Embodiments of the present invention will be discussed below in greater detail referring to the appended claims, in which:

FIG. 1 shows an exemplary simulated course of an axial magnetic flux density B_{z} of a micromagnet produced by agglomerating NdFeB (neodymium-iron-boron) powder in accordance with an embodiment;

FIG. 2 shows a schematic side view of a microsystem in accordance with an embodiment;

FIG. 3a shows a schematic perspective view of a microsystem in accordance with an embodiment, which exemplarily comprises four permanent magnets;

FIG. 3b shows a schematic side sectional view of a part of a microsystem in accordance with an embodiment;

FIGS. 4a-b show simulation results for illustrating an influence of inventive micromagnets on a single Hall sensor;

FIGS. 5a-b show illustrations, comparable to FIGS. 4a-b, with an increased distance between the micromagnets and the Hall sensor;

FIGS. 6a-b show schematic graphs of a course of a magnetic field exemplarily for a sensor element in accordance with an embodiment;

FIG. 7a shows schematic graphs of magnetic fields which can be obtained at different distances to the magnets, in accordance with an embodiment;

FIG. 7b shows a schematic top view of a support element in accordance with an embodiment;

FIG. 8a shows schematic graphs of courses of signal changes in dependence on the size of the magnets;

FIG. 8b shows an exemplary table of potential numeral values of cross talk when using inventive magnets;

FIG. 9a shows a schematic side sectional view of a microsystem in accordance with an embodiment, in which a first a first support element is arranged to be movable relative to a second support element by means of a movement in parallel to the z axis and/or by rotation around the y axis;

FIG. 9b shows a schematic side sectional view of the microsystem of FIG. 9a in a configuration in accordance with an embodiment, in which the first support element, alternatively or additionally to the explanations in FIG. 9a, is configured for a movement in parallel to the x axis and/or for a movement as a rotation around an axis parallel to the z axis;

FIG. 10a shows a schematic side sectional view of a microsystem in accordance with an embodiment, in which the permanent-magnetic means exemplarily comprises a single permanent magnet, whereas the sensor means comprises a different number of sensor elements;

FIG. 10b shows a schematic side sectional view of a microsystem, modified when compared to the microsystem of FIG. 10a, in accordance with an embodiment in which the second support element is shaped so as to comprise a recess;

FIG. 11 shows a schematic side sectional view of a microsystem in accordance with an embodiment, implemented for correcting disturbing influences;

FIG. 12 shows a schematic side sectional view of a microsystem in accordance with an embodiment, having a reference magnetic field source;

FIG. 13 shows a schematic flow chart of a method in accordance with an embodiment;

FIGS. 14a-b show exemplary illustrations of well-known concepts for capacitive position detection using planar or comb-like electrode pairs;

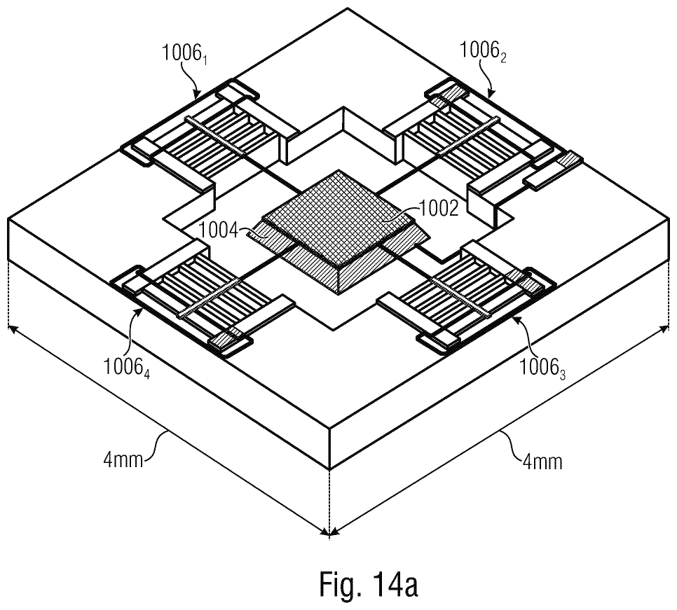

FIG. 15a shows an illustration of a well-known magnetic linear scale; and

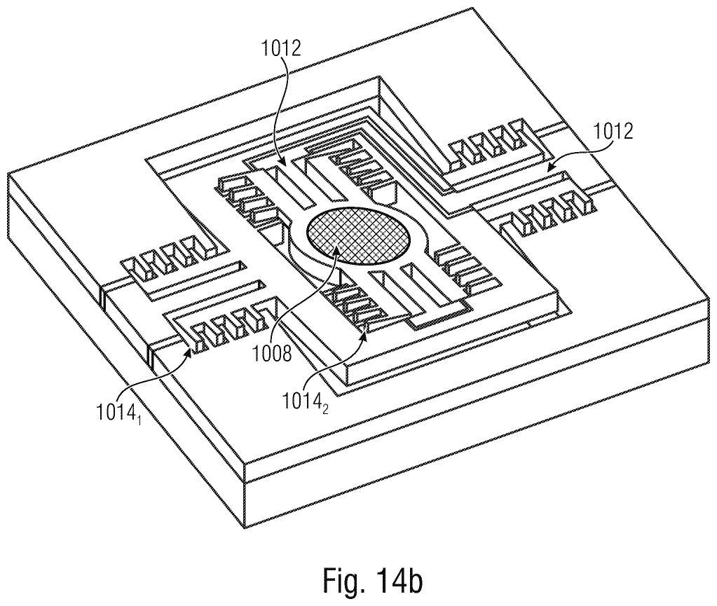

FIG. 15b shows an illustration of a well-known tactile sensor consisting of a magnet which is enclosed by an elastomer.

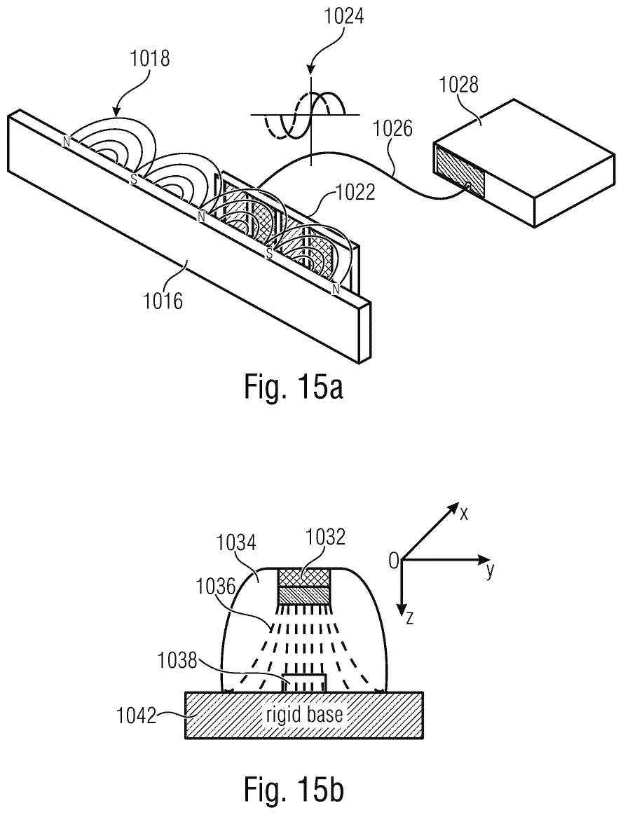

### DETAILED DESCRIPTION OF THE INVENTION

Before discussing embodiments of the present invention below in greater detail referring to the drawings, it is pointed out that identical elements, objects and/or structures or those of equal function or equal effect are provided with equal reference numerals in the different figures so that the description of these elements illustrated in different embodiments is mutually exchangeable or mutually applicable.

Some of the embodiments described below refer to microsystems. Microsystems generally refer to systems which are manufactured in small scales in the range of millimeters, micrometers or even nanometers. Even though semiconductor materials, due to the manufacturing processes, are particularly suitable for such structures, the embodiments are not limited thereto, so that, as an alternative or in addition to semiconductor materials and, in particular, MEMS (micro-electro-mechanical system) processes, other materials, like metal materials or inorganic materials, like resins or the like, can also be used.

Some of the embodiments described below refer to micromagnets which are produced by agglomerating powder by means of atomic layer deposition (ALD). Such methods are described, for example, in [13] or [14]. The inventors have realized that such methods offer a promising solution when being applied to magnetic particles, like those comprising NdFeB materials, i.e. an NdFeB powder. These may be applied, for example, onto substrates, like those comprising a semiconductor material like silicon, and can allow extraordinary magnetic characteristics of good reproducibility. The inventors have found out that any geometries having structural widths of between 25 μm and 2000 μm, for example, can be realized in the substrate plane. A height of the micromagnets can, for example, be up to 100 μm, 200 μm, 300 μm or more, for example up to 500 μm.

Embodiments make use of the magnetic field of micromagnets integrated in the movable structure, for position detection. Integrated in the movable structure means that a magnetic element may, for example, be arranged in a recess of the substrate. However, this is not absolutely necessary since the substrate may still be changed after arranging a permanent-magnetic means. Thus, particles may be introduced into a recess, for example, these may be solidified and substrate around the three-dimensional structure obtained in this way be removed subsequently to expose the permanent-magnetic means at least partly. When translating and/or tilting the movable structure, the magnetic field generated by the integrated micromagnets will shift correspondingly. The signal detected by an arrangement of potentially spatially fixed magnetic field sensors changes in correspondence with the shift of the magnetic field and thus allows drawing conclusions as to the translation and/or tilting of the movable structure.

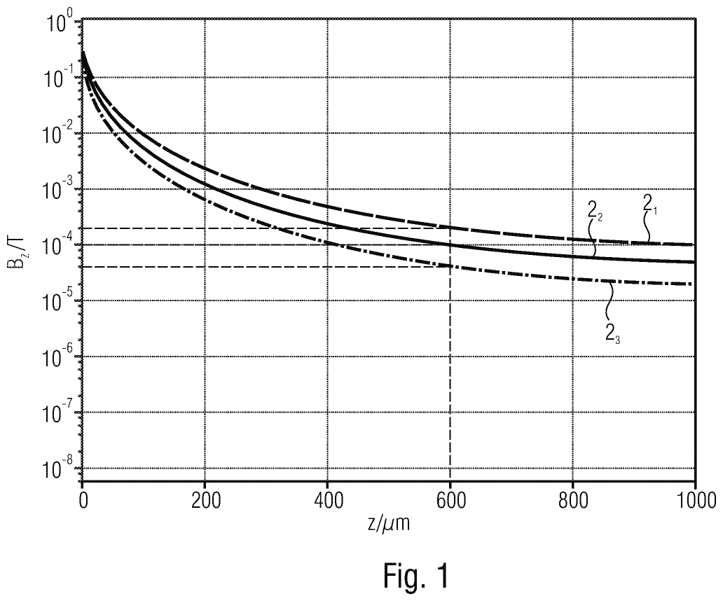

FIG. 1 shows an exemplary simulated course of an axial magnetic flux density B_{z} of a micromagnet produced by agglomerating NdFeB (neodymium-iron-boron) powder, in three variations, the variations each comprising a diameter d of 50 μm, wherein the diameter here refers to a dimension in the substrate plane, like a whole diameter of a cavity. The micromagnets may comprise different lengths, which may correspond to a depth of the cavity. The course 2₁ exemplarily refers to a length of 250 μm, the course 2₂ to a length of 150 μm and the course 2₃ to a length of 50 μm. It becomes obvious that, even for the course 2₃, with a distance of 600 μm, a magnetic field strength of approximately 0.1 mT can still be achieved, and even more with deeper magnets. The increase in the flux density decreases strongly with an increasing aspect ratio starting from an aspect ratio of 5:1, wherein field strengths of this order of magnitude, however, are relatively easy to measure by means of modern magnetic field sensors. Arrays of powder-based micromagnets having a large aspect ratio, manufactured by means of the method patented in [14], are described, for example, in [15] for producing two-dimensional magnetic field patterns for applications like magnet scales.

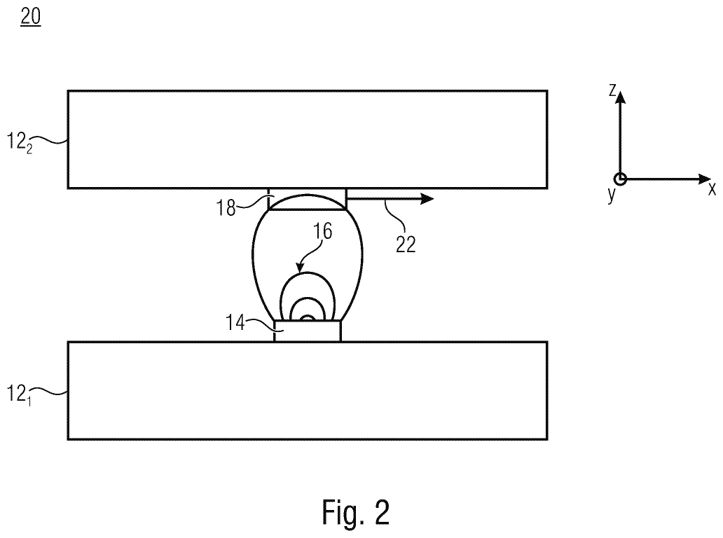

FIG. 2 shows a schematic side view of a microsystem 20 in accordance with an embodiment. The microsystem 20 comprises support elements 12₁ and 12₂ which are arranged to change a relative position to each other. This can be performed by moving the support element 12₁ and/or 12₂ along one or more spatial directions x, y and/or z. The support elements 12₁ and/or 12₂ may comprise equal or mutually different materials. Exemplarily, the support elements 12₁ and/or 12₂ may comprise a semiconductor material, wherein each of the support elements 12₁ and/or 12₂ may also comprise a sequence of layers in which a semiconductor material in a doped or undoped state alternates with other semiconductor-based materials, like insulation materials, like SiO or SiN or the like, and/or in which conducting materials, like metal materials, are arranged. Exemplarily, the microsystem 20 is an MEMS. The support elements may alternatively or additionally comprise a glass material or a ceramic material, wherein combinations of these materials and/or combinations of the materials with other materials are also included here.

The support element 12₁ is a movable support element, for example. The support element 12₂ may comprise a substrate such that the sensor signal 22 indicates a position of the movable support element 2₁ relative to the substrate 12₂. Alternatively, the support element 12₂ may be movable and the support element 12₁ may be a substrate and/or both support elements may be movable relative to a third structure.

The microsystem 20 comprises a permanent-magnetic means 14 configured to generate a magnetic field 16 based on the permanent-magnetic characteristic. The permanent-magnetic means may be connected fixedly to the support element 12₁ or 12₂, wherein a mechanically fixed connection is of advantage. A mechanically fixed connection can be understood to be an approximately rigid connection to each other. Exemplarily, the permanent-magnetic means 14 may be arranged by means of a depositing method, a gluing method or another mounting method.

Embodiments relate to the fact that the permanent-magnetic means 14 is a three-dimensional structure obtained by means of solidifying particles by means of atomic layer deposition or the like. This deposition of a coating of the particles may at the same time be made use of to obtain a fixed connection between the support element 12₁ and the permanent-magnetic means 14.

The microsystem additionally comprises a sensor means 18 connected to the other one of the support elements, like the support element 12₂, in a mechanically fixed manner. The mechanically fixed connection between the sensor means 18 and the support element 12₂ can be obtained based on a mounting process or gluing process. The sensor means 18 is configured to detect the magnetic field 16 and to provide a sensor signal 22 which is based on the magnetic field 16. The sensor signal 22 indicates a relative position of the support elements 12₁ and 12₂ since an amplitude of the magnetic field detected by the sensor means 18 and/or other characteristics, like directional components or the like, are variable based on a variable relative position. Implementations allow the sensor signal 22 to unambiguously indicate the relative position of the support elements 12₁ and 12₂ relative to each other.

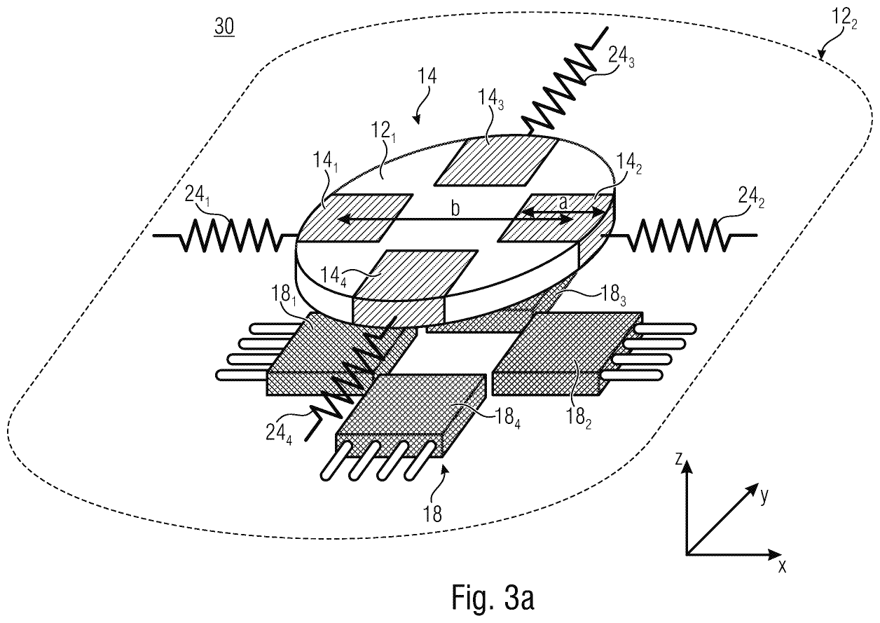

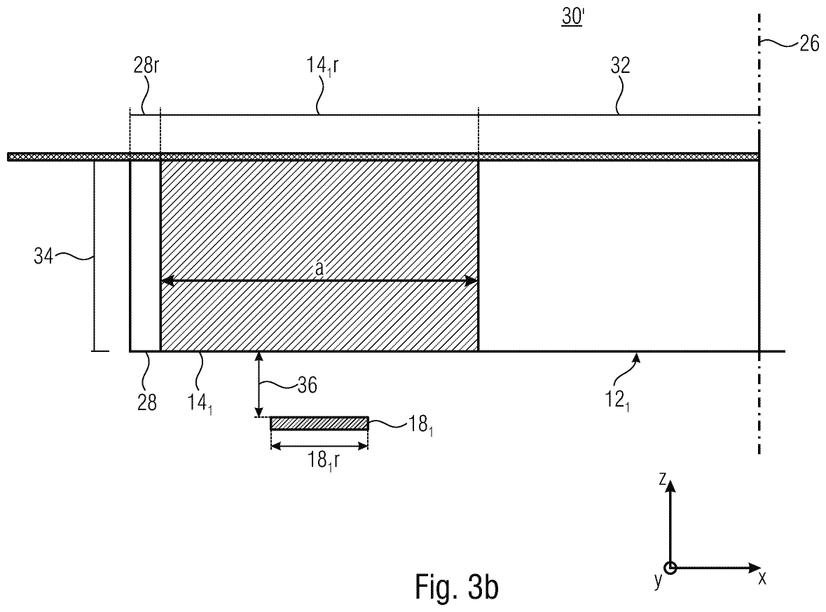

FIG. 3 shows a schematic perspective view of a microsystem 30 in accordance with an embodiment. The permanent-magnetic means of the microsystem 30 may exemplarily comprise four permanent magnets 14₁-14₄. The support element 12₁ may exemplarily be formed as a circular disk or cylinder which is supported relative to the support element 12₂ via one or more spring elements 24₁-24₄. The spring elements 24₁-24₄ may exemplarily be arranged symmetrically around the support element 12₁, but not necessarily. The support element 12₁ may be movable with regard to the relative position to the support element 12₂ based on the spring elements 24₁-24₄, like based on a rotation around one or more of the x, y or z axes, and/or based on a lateral shift along one or more of these axes.

The spring elements 24₁ to 24₄ may connect or support the support element 12₁ relative to the support element 12₂. As an alternative to a number of four spring elements, any other number greater than 1 can be used. The at least one spring element may preset an advantageous direction of movement to change the relative position between the support elements 12₁ and 12₂. Thus, torsion spring element may exemplarily preset a torsion, whereas bending elements are deformable along an advantageous bending direction and are formed to be stiff along directions perpendicular thereto. The support element 12₁ and/or the support element 12₂ may exemplarily be formed to be plate elements. The plate element may exemplarily comprise a mirror or be a mirror. However, any other functions may also be implemented. Embodiments provide for microsystems which are formed to be scanners, electrical switches, optical switches, valves or pumps.

A direction of a change in the relative position may be based on at least an orientation of a spring element between the support elements 12₁ and 12₂. Alternatively or additionally, the direction of the change in the relative position may be based on at least a rotational axis for allowing rotation of the at least one of the support elements 12₁ and 12₂. Alternatively or additionally, the direction of a change in the relative position may be based on at least a limitation surface or limitation edge along which movement of the support elements 12₁ and/or 12₂ is preset. Such a limitation surface or limitation edge may, for example, be a mechanical stop.

Exemplarily, the support element 12₁ is movable relative to the support element 12₂ in the x, y plane or parallel thereto, for example. The x/y plane may thus describe a plane of the change in relative position. At least one, several or all of the permanent-magnetic elements 14₁ to 14₄ may be arranged in this plane relative to the sensor elements of the sensor means 18. With regard to the sensor elements 18₁ to 18₄, the magnetic elements 14₁ to 14₄ may be arranged to be perpendicular thereto, i.e. along the z direction which is arranged to be perpendicular to the x/y plane. In the arrangement in accordance with the microsystem 30, the permanent-magnetic means 18 may comprise a number of at least one, for example four, permanent-magnetic elements 14₁ to 14₄ for generating a magnetic field associated to the respective permanent-magnetic element 14₁ to 14₄. The sensor means 18 may comprise a corresponding number of sensor elements 18₁ to 18₄. Exemplarily, precisely one sensor element 18₁ to 18₄ may be associated unambiguously to each permanent-magnetic element 14₁ to 14₄. In the example of FIG. 3a, this is done by the opposing arrangement of permanent magnets 14ᵢ and sensor elements 18ᵢ, with i=1, 2, 3, 4. This allows the number of permanent-magnetic elements 14 to be arranged to be in mirror-symmetrical opposition to the sensor elements 18 in a rest position of the microsystem 30, wherein a plane in parallel to the x/y plane is the mirror plane.

Exemplarily, the permanent magnets 14₁-14₄ are integrated in a material or structure of the support element 12₁, which may exemplarily be obtained by forming, in the support element 12₁, cavities which are filled with magnetic particles and subsequently solidified by a coating process. By subsequently planarizing one or more surfaces, a homogenous surface structure can be obtained. Even without planarizing, one or more permanent magnets 14₁-14₄, i.e. magnetic elements, may be structurally integrated in the support element 12₁.

The sensor means 18 may comprise one or more sensor elements 18₁-18₄ which are each configured to provide a measuring signal. Exemplarily, the sensor elements 18₁-18₄ may be implemented to be Hall elements for detecting a spatial magnetic-field component, or Hall sensors for detecting several spatial components.

Exemplarily, one sensor element 18₁-18₄ each may be associated to a corresponding permanent magnet 14₁-14₄. In a rest position of the microsystem 30, for example, a respective permanent magnet 14₁-14₄ may comprise a reference position relative to an associated sensor element 18₁-18₄, for example be arranged to be centered thereto.

Based on a shift of the relative position between the support elements 12₁ and 12₂, a respective position of the permanent magnet 14₁ to 14₄ relative to the sensor element 18₁ to 18₄ can be varied so that one or more of the sensor signals of the sensor elements 18₁ to 18₄ may change. Exemplarily, with a rotation around the x axis, a signal of the sensor elements 18₁ and 18₂ may remain approximately constant, whereas, with a rotation around the y axis, for example, sensor signals of the sensor elements 18₃ and 18₄ may remain approximately constant. Other relative changes in position result in other changes or uniformity in sensor signals. Mechanical boundary conditions relative to the change in the relative position may also be considered here. Exemplarily, permanent magnets 14ᵢ, with i=1, . . . , n with n≥1, may exemplarily be arranged such that the mechanically allowable or provided changes in the relative movement can be detected. If, starting from a final position, for example, a movement is possible only along one direction, arranging a single permanent magnet may already be sufficient. If a movement is possible along one axis, but in two directions, when using only one permanent magnet, ambiguities may result in the measuring signal, which can be rectified by arranging a second permanent magnet and/or a second sensor element. Additional directions can be covered by additional permanent magnets and/or sensor elements.

FIG. 3b shows a schematic side sectional view of a part of a microsystem 30′ in accordance with an embodiment. When compared to the microsystem 30, the support element 12₁ is formed to be slightly amended, for example such that, along a radial direction, like the negative x direction, when starting from an axis of symmetry 26, the magnetic element or permanent magnet 14₁ may be, different from what is shown in FIG. 3a where it may form an outer edge of the support element 12₁, surrounded by an outer edge 28. The outer edge 28 may comprise a support material or base material of the support element 12₁. Exemplarily, such a structure can be obtained when a cavity for being filled with magnetic particles remains surrounded by the edge region 28 and is not exposed by means of an etching process or the like, for example, or the cavity is not placed at the terminal or edge of the support element 12₁. Although this may reduce a maximum possible distance between two neighboring or opposite permanent magnets, this allows advantages in manufacturing, for example, since the material of the outer edge 28 is easier to process than the permanent magnet 14₁. A dimension 28r of the outer edge 28 along the x direction may, for example, comprise any value as small as desired, wherein embodiments provide for maximum values of 100 μm, 75 μm or 50 μm. A dimension 14₁r or a dimension a of the permanent magnet 14₁ along the radial direction x may comprise any value. Exemplarily, the value a is implemented so as to comprise a value of at least 20 μm and at most 2000 μm, at least 100 μm and at most 1500 μm or at least 500 μm and at most 1000 μm, like 750 μm, for example. This means that the permanent-magnetic means may comprise at least one permanent-magnetic element, wherein the permanent-magnetic element may, perpendicularly to a thickness direction z, comprise a first translatory dimension, for example along x, and a second perpendicular translatory dimension, for example y. The first translatory dimension and/or the second translatory dimension may comprise a value of at least 20 μm and at most 2000 μm.

A distance 32 between the axis of symmetry 26 and an outer edge of the permanent magnet 14₁, facing the axis of symmetry 26, may also comprise any value which may, for example, depend on the application of the microsystem. Exemplarily, the distance 32 comprises a value of at least 50 μm and at most 5 mm, at least 100 μm and at most 3 mm, or at least 200 μm and at most 1 mm, like 450 μm, for example. In the case of a symmetrical implementation of the support element 12₁, double a value of the distance 32 may describe a distance or gap between two opposite permanent magnets, for example the permanent magnets 14₁ and 14₂ of the microsystem 30.

The distance 32 and the dimension a here may be selected such that a distance of the permanent-magnetic elements among one another is selected such that a detection of the magnetic field of a permanent-magnetic element at the location of a sensor element associated thereto is influenced at most insignificantly, by fields of adjacent permanent-magnetic elements. An insignificant influence here may, for example, be understood to be such that the magnetic field of a permanent-magnetic element is at most 10%, at most 5% or at most 2% compared to an amplitude of the magnetic field of another permanent-magnetic element at the location of the sensor element associated to the other permanent-magnetic element. This means that a magnetic field amplitude of the permanent-magnetic element 14₁, at the position of the sensor elements 18₂, 18₃ or 18₄ of the microsystem 30, for example, is at most 10%, at most 5% or at most 2%. This may be done by correspondingly adjusting a distance b, which exemplarily relates to centers of main side surfaces of the permanent magnets.

In the arrangement of the microsystem 30 shown, the distance 32 to the axis of symmetry and double the value thereof to the opposite permanent-magnetic element is, for example, greater a distance than to directly adjacent permanent-magnetic elements 14₃ and 14₄. The distance to both the opposite and to the directly adjacent permanent magnets 14₂, 14₃ and 14₄ here may be selected such that each of the permanent magnets 14₁ to 14₄ comprises a distance to any other permanent magnet, i.e. in any pairing, which is at least 50 μm, at least 70 μm or at least 100 μm. Alternatively or additionally, the distance may be at least double a lateral dimension of the permanent magnet and the other permanent magnet used for forming pairs, along the respective connective direction. The connective direction is, for example, arranged along the x direction between the permanent magnets 14₁ and 14₂, along they direction between the permanent magnets 14₃ and 14₄, and along a diagonal direction between the permanent magnets 14₁ and 14₃ or 14₁ and 14₄. Thus, the distance may exemplarily correspond to double the value of a.

The sensor element 18₁ may comprise, along the radial direction x, an extension or dimension 18₁r which may be smaller than the dimension a, wherein other embodiments are also possible. Exemplarily, the dimension 18₁r comprises a value of at least 1 μm and at most 300 μm, at most 200 μm or at most 170 μm, like 150 μm, for example. Although some embodiments provide for dimensions of at least 20 μm, the dimension may also be below 20 μm. Exemplarily, such small magnets may be used individually or in a plurality or multitude, for example by arranging many sensor elements in an array. Such an array can be considered to be a compound or group of several magnets, or an individual, combinatorial magnetic element.

The permanent magnet 14₁ may comprise a thickness or length, i.e. a dimension along the direction z perpendicularly to the axial direction, which is referred to as thickness 34 and may exemplarily comprise a value of at least 50 μm and at most 1000 μm, at least 100 μm and at most 700 μm or at least 200 μm and at most 500 μm, like 300 μm, for example.

A distance 36 between mutually facing surfaces of the permanent magnet 14₁ and the sensor element 18₁, in a rest position of the microsystem 30 or 30′, may, for example, comprise a value of at most 2000 μm, at most 800 μm or at most 600 μm and be adjusted to the intended or tolerable movement of the support element 12₁ relative to the support element 12₂. This means that a design of the amplitudes of movement to be monitored relative to a change of the relative position can be taken into consideration. A minimum distance may also be adapted to the movement and be at least 10 μm, at least 70 μm or at least 100 μm, for example. This means that the support elements 12₁ and 12₂, in a rest position of the microsystem, may comprise a distance 36 of at least 10 μm and at most 2000 μm.

Adjacent permanent-magnetic elements, for example, 14₁ and 14₃ or 14₁ and 14₄, may comprise mutually different magnetic field orientations. Exemplarily, north poles of mutually adjacent permanent magnets may be facing each other or, alternatively, south poles.

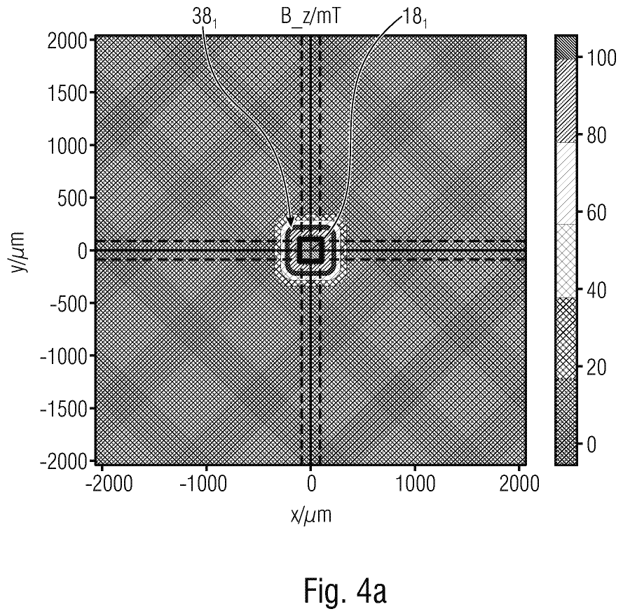

In other words, FIG. 3a schematically shows an exemplary arrangement comprising a moveable, spring-suspended platform, for example made of silicon, having four integrated micromagnets and four Hall sensors located below and fixed to the ground. Important dimensions are represented in the cross-section drawing of FIG. 3b. The platform in this exemplary arrangement may comprise a diameter of 2000 μm and a height of 300 μm, i.e. the sum of the distances 28r, 14₁r and 32, based on the symmetry, may be 1000 μm, whereas the dimension 34 may be 300 μm. The edge length a of the possibly squared magnets at their corners may, for example, be 500 μm, the distance b from center to center may be 1400 μm. The magnets extend over the full thickness of the platform. An Si edge having a width of 50 μm remains along the perimeter of the platform. This Si edge is not illustrated in FIG. 4a. The active area of the Hall sensors may, for example, be 150 μm×150 μm and exemplarily be on an axis centered with the respective magnets. The axis may, for example, be arranged perpendicularly to a movement plane. A movement, for example in the x/y plane, may thus serve to implement a corresponding axis along the z direction or parallel thereto, as is illustrated in FIG. 3a. FIGS. 3a and 3b thus show schematic illustrations of an arrangement comprising a spring-suspended Si platform having four integrated micromagnets, and four Hall sensors positioned below and fixed to the ground, wherein FIG. 3b shows a cross-section of a platform half potentially drawn to scale.

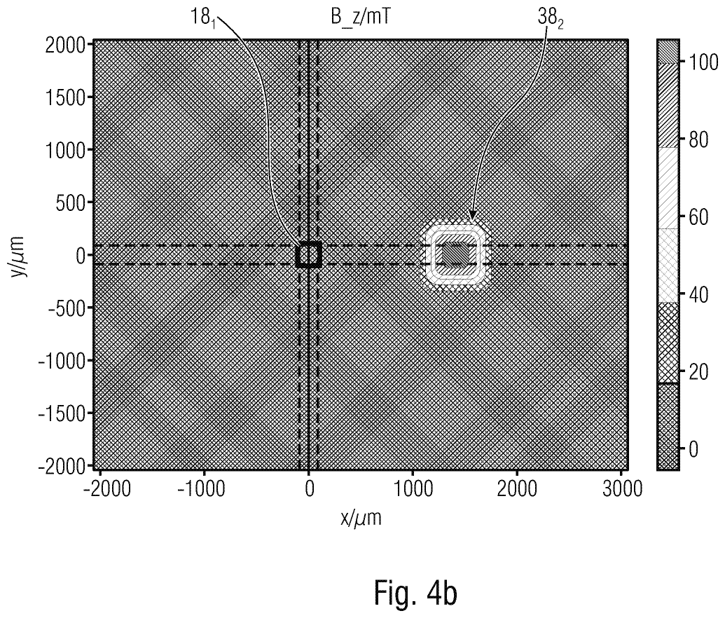

FIGS. 4a and 4b illustrate the influence of the magnets, for example of the permanent magnets 14₁ and 14₂ of FIG. 3a, on an individual Hall sensor, for example the sensor element 18₁. The distance 36 exemplarily is 100 μm. The magnet 14₁ can generate a strong magnetic field which reflects its geometry and the maximum of which almost completely covers the Hall sensor 18₁. As is shown in FIG. 4b, cross talk of the magnet 14₂ on the Hall sensor 18₁, however, is small. This state is also maintained for a distance 36 of 300 μm as is shown in FIGS. 5a and 5b. FIG. 4a in contrast, in a schematic top view, shows an intensity of a magnetic field 38₁ of the permanent magnet 14₁ at the position of the sensor element 18₁. FIG. 4b, in the same perspective as FIG. 4a, shows an intensity of a magnetic field 38₂ of the permanent magnet 14₂, wherein it becomes obvious that this magnetic field does not influence, or at most to an insignificant degree, influence the measurement of the sensor element 18₁.

FIGS. 5a and 5b show illustrations, corresponding to FIGS. 4a and 4b, in which the distance 36 is increased to 300 μm. A propagation of the magnetic field 38₁ and 38₂ may comprise larger an area, but based on the distances between the permanent magnets 14₁ and 14₂ still so small that a measurement of the sensor element 18₁ is uninfluenced or influenced only to a small degree by adjacent permanent magnets 14₂.

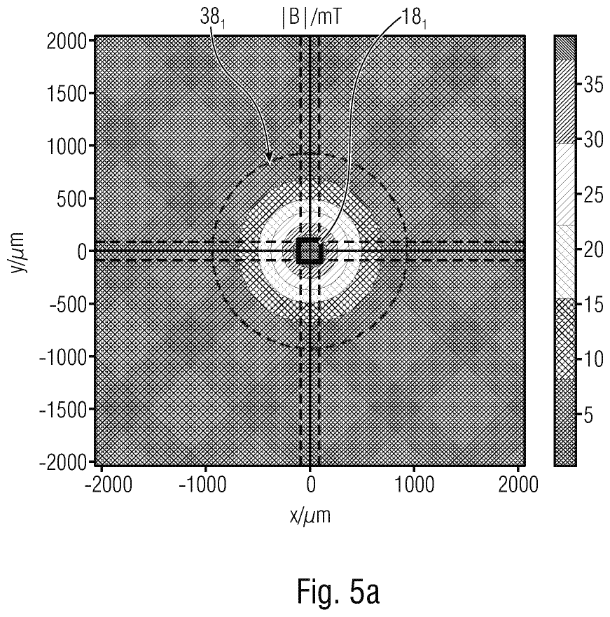

FIGS. 6a and 6b show schematic graphs of a course of a magnetic field B_{z}, exemplarily for the sensor element 18₁. With an increasing distance dₛₑₙₛ, which may, for example, be detected in μm and correspond to the distance 36, the magnetic field of the permanent magnet 14₁ may decrease, whereas the magnetic field of the magnet 14₂ is already small and may remain constant in the region of a zero value.

FIG. 6b shows a derivative of the curves of FIG. 6a, from which also becomes obvious that the measuring values of the magnetic field of the permanent magnet 14₂ at the position of the Hall sensor 18₁ are low.

In other words, FIG. 6a represents the dependence of the magnetic flux density B_{z} on the distance dₛₑₙₛ between the sensor plane and the lower side of the magnets over a travel distance of 900 μm, wherein dₛₑₙₛ=100 μm may represent a rest position of the microsystem. The magnetic field B_{z} generated by the permanent magnet 14₁ in this arrangement will remain above 3 mT. At the same time, the magnetic field of the permanent magnet 14₂ (cross talk) will, as far as magnitude is concerned, remain below 5% of the magnetic field of the permanent magnet 14₁, with equal distance. For magnetic position detection, in particular the change in magnetic field in dependence on the change in position to be detected is decisive or of influence. The absolute value of the magnetic field at this position exemplarily decides only on the detectability by means of the selected magnetic field sensors and the susceptibility towards stray fields from the environment. For the example shown here, FIG. 6b shows the change in magnetic field when shifting in the z direction, corresponding to the derivative of the curves shown in FIG. 6a. Even in the case of a distance dₛₑₙₛ of 400 μm (i.e. travel distance of 300 μm), a sensitivity of better than 0.1 mT/μm can be expected.

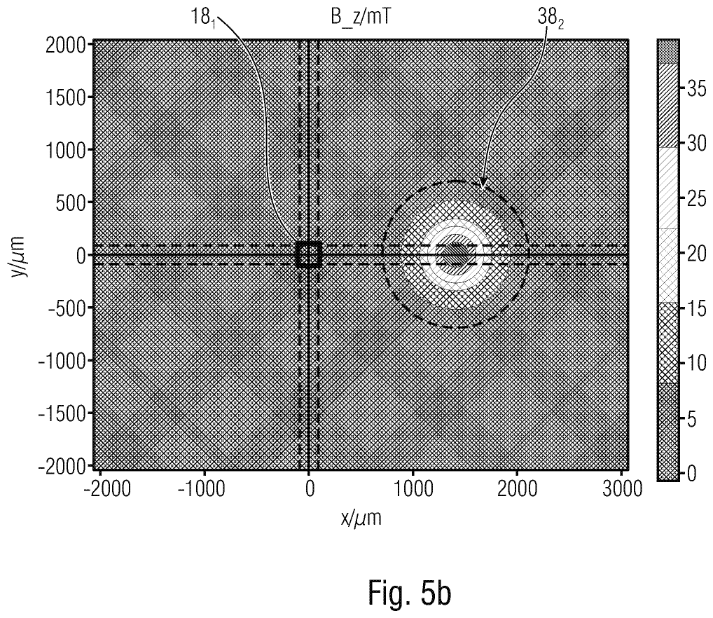

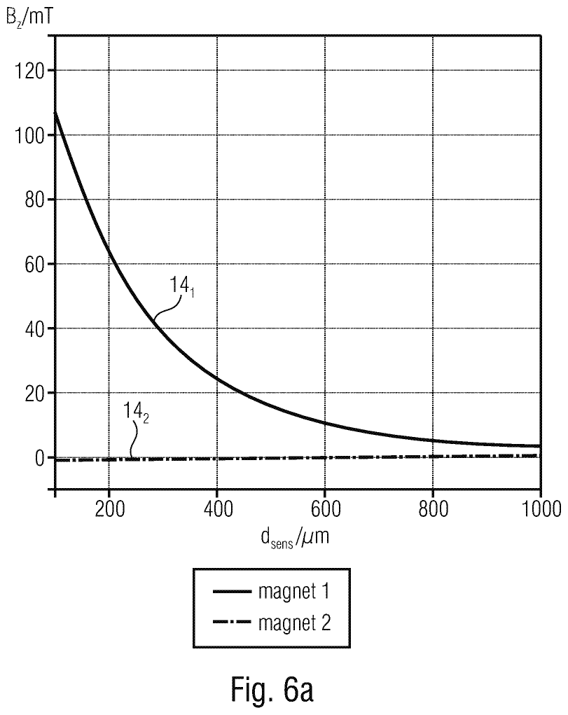

FIG. 7a shows schematic graphs of magnetic fields which can be obtained at different distances dₛₑₙₛ. The different curves 42₁ to 42₄ relate to mutually different edge lengths of exemplarily squared permanent magnets 14₁ to 14₄. Curve 42₁ relates to an edge length of 200 μm, curve 42₂ relates to an edge length of 300 μm, curve 42₃ to an edge length of 4 μm and curve 42₄ to an edge length of 500 μm. As is illustrated in FIG. 7b, which shows an exemplary schematic top view of the support element 12₁, the distance b of exemplarily 1400 μm may remain unchanged, wherein smaller dimensions may be equivalent to an expansion of the edge 28r and/or a reduction of the overall diameter 44, which exemplarily may be 2000 μm.

In other words, FIG. 7a shows courses of the magnetic flux densities B_{z} in dependence on dₛₑₙₛ and the edge length a of the magnets in FIG. 7a, and FIG. 7b a top view of the platform in accordance with FIGS. 3a and 3b for illustrating how the magnets can be scaled. The thickness of the magnets and the distance b from center to center of the magnets here may exemplarily remain constant and exemplarily be 300 μm for the thickness and 1400 μm for the distance b. FIG. 7a illustrates how the course of B_{z} is dependent on the size of the magnet. The magnets here were scaled centrically so that the distance b between opposing magnets (1400 μm) and the outer dimensions of the platform in accordance with FIG. 3a and FIG. 3b (2000 μm diameter) remain constant, as is also illustrated in FIG. 7b.

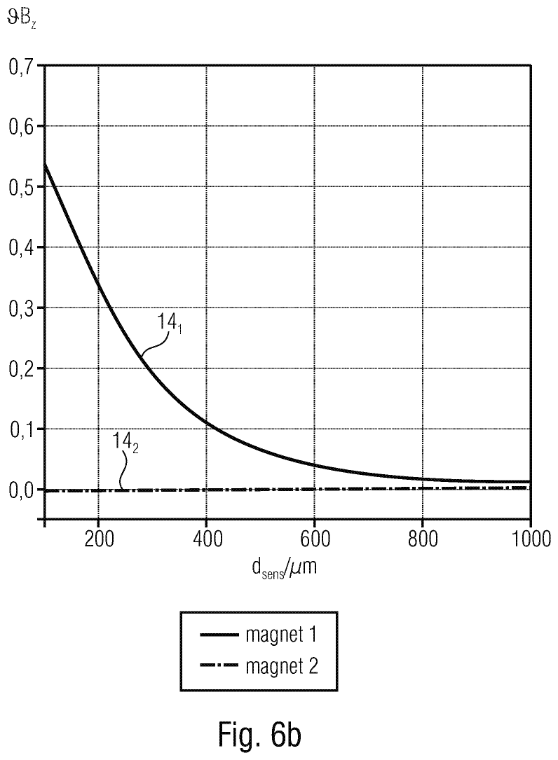

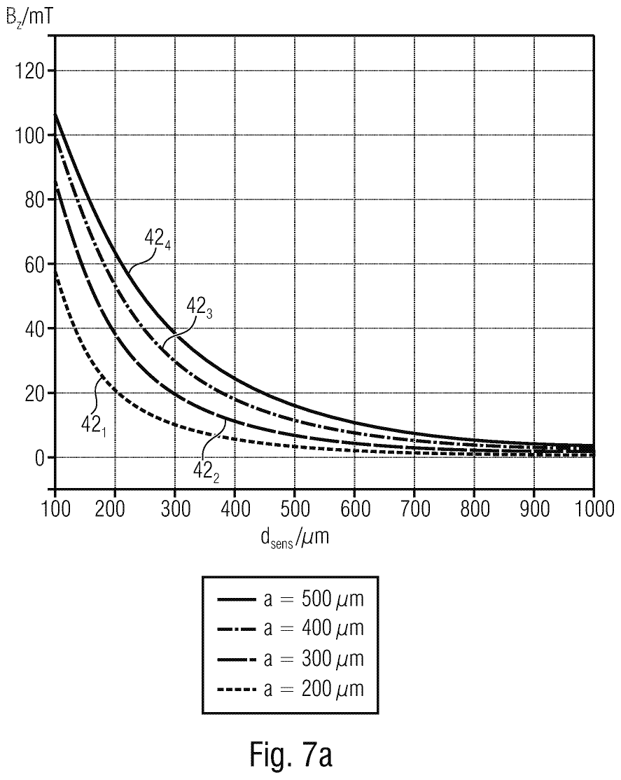

FIG. 8a shows schematic graphs of courses of signal changes, i.e. the derivative of B_{z}, λB_{z}, independence on the size of the magnets and provides an overview of the most important results of the simulation. In the case of smaller travel distances, i.e. dₛₑₙₛ>100 μm, smaller magnets are of advantage since the magnetic field here decreases over a shorter distance and thus higher a sensitivity can be achieved. In addition, cross talk decreases when using smaller magnets, as is illustrated in FIG. 8b. However, the sensitivity becomes increasingly non-linear in the case of a decreasing magnet size. Alternatively, with a decreasing edge length a, the distance b between the magnets can be reduced. This means that micromagnets having edge lengths between 20 μm and 2000 μm, and advantageously micromagnets having edge lengths between 500 μm and 1000 μm are of advantage.

In FIG. 8a, curve 46₁ shows the results for an edge length of a=200 μm, curve 46₂ a result for an edge length of a=300 μm, curve 46₃ a result for an edge length of a=400 μm and curve 46₄ a result for a=500 μm. The curves show courses of the signal changes, i.e. derivatives of B_{z}, in dependence on dₛₑₙₛ and the edge length a of the magnet in FIG. 8a, and a summary of the most important results of the simulation in FIG. 8b.

It has shown that complex positional changes of movable MEMS structures can be monitored by means of magnetic position detection using a travel range which, when compared to capacitive or piezoresistive positon detection is greater by at least one order of magnitude, with constant space requirements. Even simple implementations based on two pairs of micromagnets and sensors allow detecting both vertical shifts and tilting, i.e. also lateral shifts and twists within the plane. As has been described in connection with FIGS. 3a and 3b, by using further micromagnet-sensor pairs, in analogy, any three-dimensional changes in position can be monitored. In the results illustrated in FIGS. 4a, 4b, 5a, 5b, 6a, 6b, 7a, 7b, 8a and 8b, a magnetization of 450 mT was assumed for the integrated magnets, which is possible using to an agglomerated NdFeB powder as described. Alternatively or additionally, other hard-magnetic materials can also be used. Among these are SmCo, PtCo, AlNiCo, CoFeNi, FeCrCo and different hard ferrites, for example, and combinations thereof. When compared to optical position detection, the magnetic position detection described is cheaper, less sensitive to pollution and allows a comparably high precision.

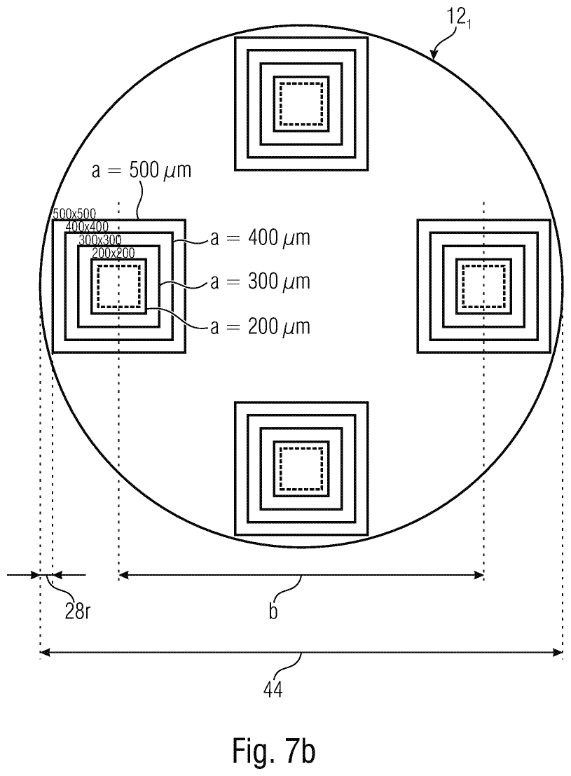

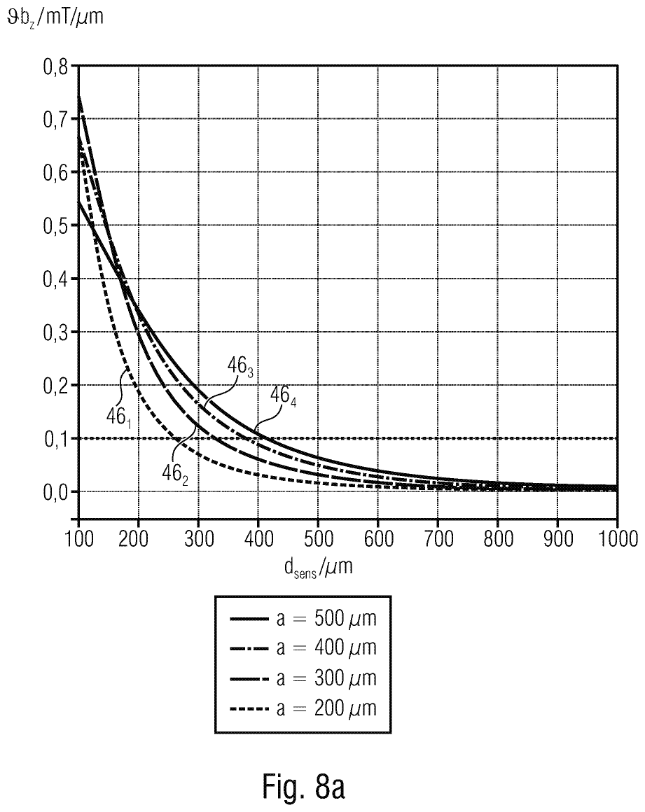

FIG. 9a shows a schematic side sectional view of a microsystem 90 in accordance with an embodiment, in which the support element 12₁ is exemplarily arranged to be movable relative to the support element 12₂ by means of a movement in parallel to the z axis and/or by a rotation around the y axis. A number of, for example, two permanent magnets 14₁ and 14₂ are arranged to be mirror-symmetrical to a plane 48 arranged in parallel to the x/y plane, relative to sensor elements 18₁ and 18₂.

While a movement 52₁ in parallel to the z axis may cause an equal change of measuring values in the sensor elements 18₁ and 18₂, a movement 522 aligned to be rotational around they axis may result in an inverse change of the measuring values. This means that the support element 12₁ can be shifted relatively with regard to the support element 12₂ along at least one axis in a translatory manner, and/or be tilted relatively to the support element 12₂.

FIG. 9b shows a schematic side sectional view of the microsystem 90 in a configuration in which the support element 12₁, as an alternative or in addition to the discussion of FIG. 9a, is implemented for a movement 52₃ in parallel to the x axis and/or for a movement 52₄ as a rotation around an axis in parallel to the z axis. Both movements 52₃ and 52₄ can result in an equal change in measuring values in the sensor elements 18₁ and 18₂, at least as far as the measuring amplitude is concerned.

In other words, FIGS. 9a and 9b show schematic illustrations of possible arrangements for detecting vertical shifts and tilts in FIG. 9a, and lateral shifts and tilts in the plane in FIG. 9b, using two micromagnet-sensor pairs 14₁/18₁ and 14₂/18₂.

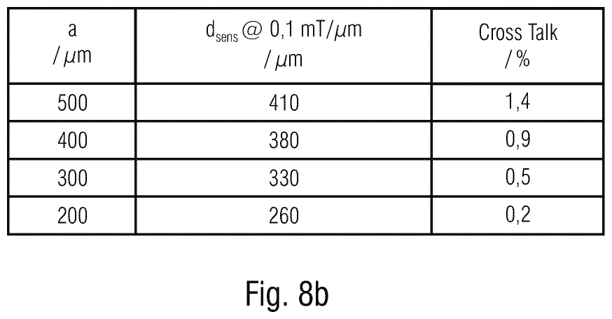

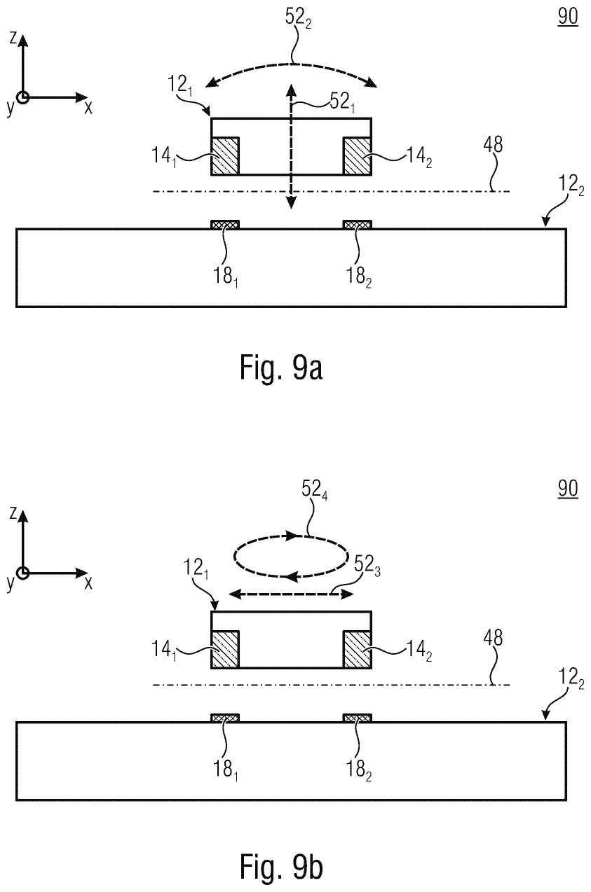

FIG. 10a shows a schematic side sectional view of a microsystem 100 in accordance with an embodiment, in which the permanent-magnetic means exemplarily comprises a single permanent magnet 14₁, whereas the sensor means comprises a respective different number of sensor elements 18₁ and 18₂. The permanent-magnetic means and/or the sensor means can comprise a higher number of elements. In the embodiment of FIG. 10a, the sensor element 18₁ and the sensor element 18₂, maybe additional sensor elements, are associated to the permanent-magnetic element 14₁. This means that the sensor elements 18₁ and 18₂ are arranged to be spatially adjacent to the permanent magnet 14₁, advantageously such that in the case of a movement of the support elements 12₁ and 12₂ relative to each other, a marked measuring signal can be determined in both sensor elements 18₁ and 18₂. The sensor means 18 may comprise calculating means 54, for example an application-specific integrated circuit (ASIC), microcontroller, processor or the like, configured to differentially evaluate the sensor elements 18₁ and 18₂ such that the sensor signal 22 is based on the differential evaluation of the magnetic field of the permanent magnet 14₁ by measuring with at least the sensor values 18₁ and 18₂.

This means that the sensor means 18 exemplarily comprises at least one sensor element and the evaluating circuit 54 which together form at least a part of an application-specific integrated circuit (ASIC).

As has been described in connection with the microsystem 30 or 90, the permanent-magnetic means and the sensor means may be arranged in different planes 481 and 48₂.

FIG. 10b shows a schematic side sectional view of a microsystem 100′ modified compared to the microsystem 100. The support element 12₂ here is shaped so as to provide a recess or cavity 48, which alternatively may also be referred to as elevations adjacent to the support element 12₁. An elevation for the sensor elements 18₁ and 18₂ can be provided by this, so that the sensor means 18 or the sensor elements 18₁ and 18₂ and the permanent-magnetic means, in particular the permanent magnet 14₁, can be arranged in a common plane 48. The sensor elements 18₁ and 18₂ can both be associated to the permanent magnet 14₁.

In accordance with further embodiments, a microsystem comprises a permanent-magnetic means comprising at least a first permanent-magnetic element for generating a first magnetic field associated to the first permanent-magnetic element and a second permanent-magnetic element for generating a second magnetic field associated to the second permanent-magnetic element. The sensor means comprises a sensor element which is associated both to the first permanent-magnetic element and the second permanent-magnetic element, and configured to detect overlapping of the first magnetic field and the second magnetic field. In contrast to detecting a single magnetic field using several sensor elements, this means that several magnetic fields can be detected using a common sensor element.

These implementations can be combined as desired so that different permanent-magnetic elements can be associated to a single sensor element (FIG. 3a), associated to several sensor elements (FIG. 10a and FIG. 10b) and other permanent-magnetic elements be detected by several sensor elements.

In accordance with embodiments, the sensor means comprises at least one sensor element. Each sensor element of the sensor means is configured to provide a measuring signal associated to the sensor element, like an output signal of the Hall sensor. The sensor means can be configured to correct disturbing influences on the sensor element at least partly.

In other words, the micromagnet and the sensors do not necessarily have to be used in pairs. FIG. 10a and FIG. 10b show two further implementations in which two sensors 18₁ and 18₂ each are associated to a micromagnet 14₁. This allows evaluating differential signals. This in turn allows a higher precision and eliminating error sources. FIGS. 10a and 10b show schematic illustrations of possible arrangements for detecting lateral shifts, wherein two sensors 18₁ and 18₂ each are associated to a micromagnet 14₁ to allow differential measurements. In the arrangement in accordance with FIG. 10a, the micromagnet may be magnetized perpendicularly to the plane, i.e. along the z direction. In the arrangement in accordance with FIG. 10b, a magnetization within the plane, i.e. in the x/y plane, may be of advantage.

Depending on the arrangement, the micromagnets may be magnetized both perpendicularly to the plane and in the plane. The opposite magnetization of micromagnets within an arrangement is also possible. All well-known magnetic field sensors, like Hall sensors, AMR (anisotropic magnetic resistance) sensors, GMR (giant magnetic resistance) sensors or MAGFET (magnetic transistor), may be used for detection. Depending on the arrangement, measuring purpose and sensor, measurements may be performed both in the plane and perpendicularly to the plane.

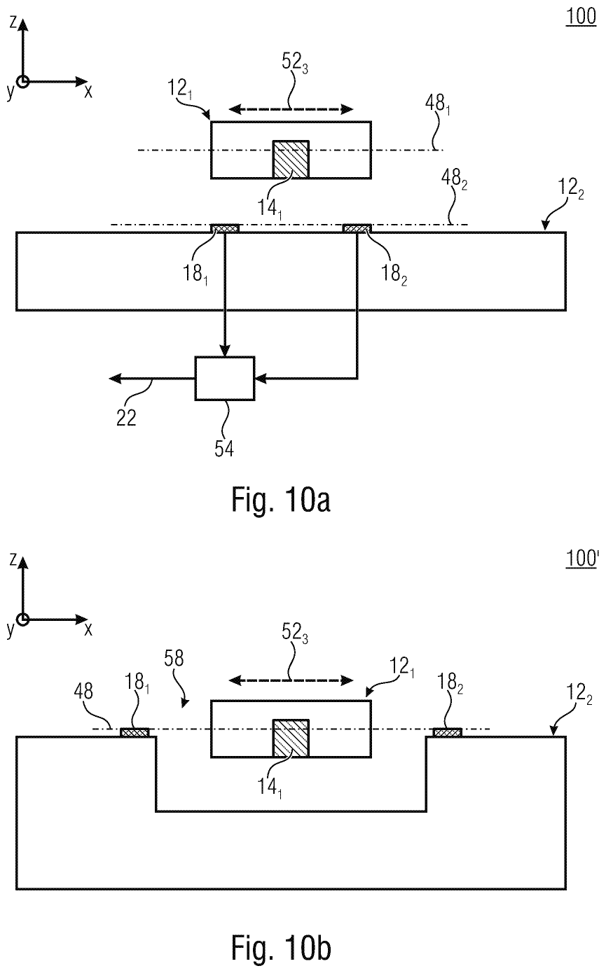

FIG. 11 shows a schematic side sectional view of a microsystem 110 in accordance with an embodiment oriented for correcting disturbing influences. The microsystem 110 exemplarily is a modification of the microsystem 100 and extends the same by a reference sensor element 18₃ of the sensor means. The reference sensor element 18₃ is configured to detect a reference magnetic field and to provide a reference signal 62. The sensor means is configured to adjust the measuring signal 64₁ of the sensor element 18₁ and/or the measuring signal 64₂ of the sensor element 18₂ or the sensor signal 22 or a combination thereof using the reference signal 62 to correct the disturbing influences which may affect the sensor elements 18₁ and/or 18₂, at least partly. The sensor element 18₃ may exemplarily be arranged outside a magnetic field of the permanent magnets 14₁ and 14₂. The reference magnetic field may exemplarily be a surrounding magnetic field of the microsystem, i.e. an environmental influence.

In other words, FIG. 11 shows an arrangement for compensating drift effects or increasing the precision based on using one or more reference sensors on the support element.

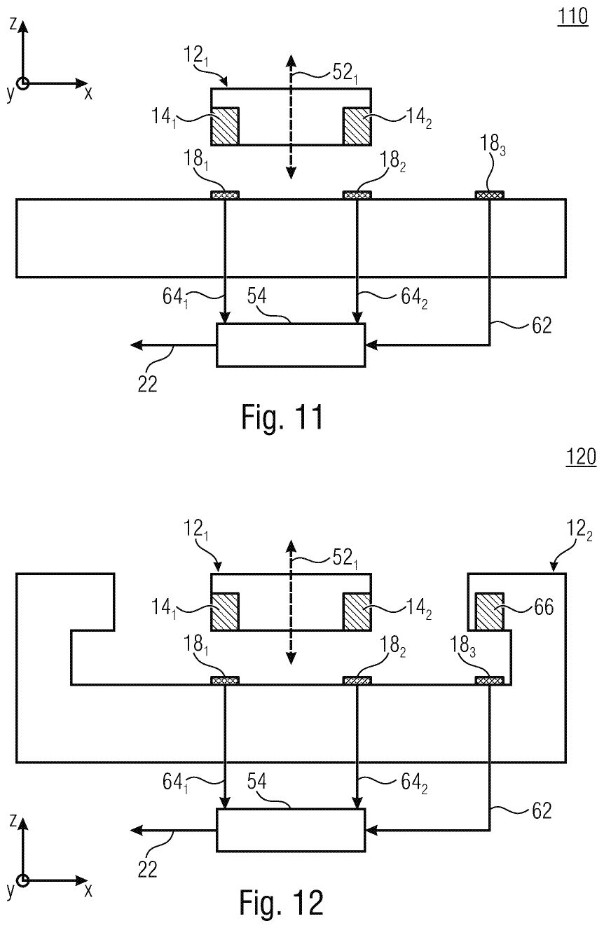

FIG. 12 shows a schematic side sectional view of the microsystem 120 in accordance with an embodiment. When compared to the microsystem 110, it comprises a reference magnetic source 66. The reference magnetic field thereof overlaps an environmental magnetic field at the position of the reference sensor so that a combinatorial magnetic field can be detected by the reference sensor. Advantageously, the reference magnetic field is implemented so as to comprise, in regular operation, i.e. with the normal earth's magnetic field, for example, a predominant portion of the magnetic field measured, at least 50%, at least 70% or at least 90%, for example.

The reference magnetic field 66 may exemplarily be part of the sensor means and be configured to generate a reference magnetic field which is detected by the reference sensor element 18₃. This exemplarily allows detecting the reference magnetic field 66 as an artificially generated magnetic field, alternatively or in addition to detecting environmental influences. Exemplarily, the reference magnet 66 may be formed similarly or identically to the permanent magnets 14₁ and 14₂ so that a degradation or aging of the immobile reference magnets 66 can be detected using the reference signal 62, which may be taken into consideration for the signal evaluation of the measuring signals 64₁ and 64₂. It is of advantage to fix the reference magnetic source 66 and the reference sensor element 18₃ to each other relative to a relative position to obtain reliable measuring results.

The microsystem 110 and the microsystem 120 can be implemented such that the reference signal 62 is entirely or partly uninfluenced by a change in the relative position between the support elements 12₁ and 12₂. Thus, the reference signal 62 is basically uninfluenced, for example, if subjected to a change of at most 10%, at most 5% or at most 2%, when changing the relative position between the support elements 12₁ and 12₂.

A potentially important basic requirement to each detection method is high to maximum an independence on environmental influences. Apart from manufacturing tolerances and intrinsic drift effects, environmental temperature and/or electromagnetic stray fields, for example, which may considerably influence or corrupt the sensor signal, may be disturbing. By integrating additional reference sensors and/or reference micromagnets on the support elements, such an effect can be minimized. In the implementation in accordance with FIG. 11, a reference sensor 18₃ is positioned to be spaced apart on the support element 12₂, so that its signal is not influenced by a change in position of the micromagnets 14₁ and 14₂ on the movable microstructure 12. In the structure in accordance with FIG. 12, a sensor-micromagnet reference pair 66/18₃ which is spaced apart from the movable microstructure is used. The advantage here is that drift and alteration effects of the micromagnets can be compensated. The dimensions of the micromagnets for reference measurement and detection may be different, but equal dimensions are not excluded.

In other words, FIG. 12 shows an arrangement for compensating drift effects or increasing the precision, based on using one or more sensor-micromagnet reference pairs on the support element.

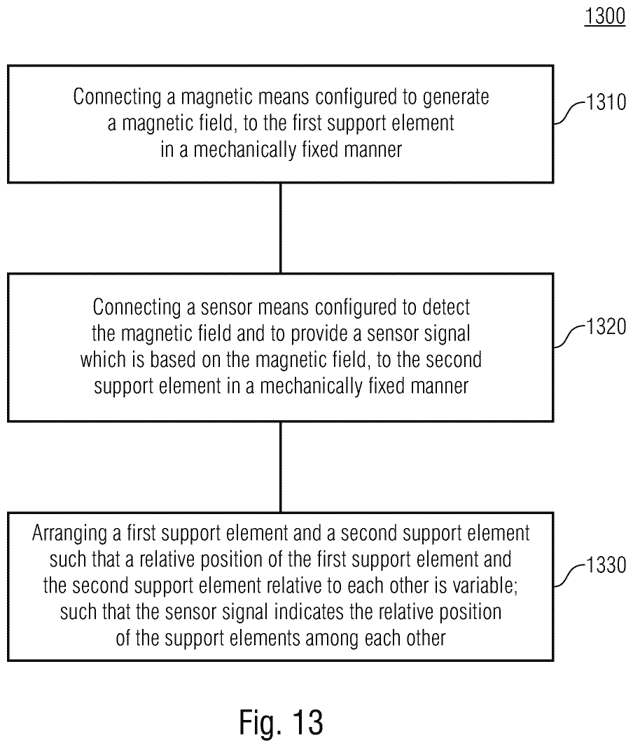

FIG. 13 shows a schematic flow chart of a method 1300 in accordance with an embodiment. Step 1310 comprises connecting a magnetic means configured to generate a magnetic field, to the first support element in a mechanically fixed manner. Step 1320 comprises connecting a sensor means configured to detect the magnetic field and to provide a sensor signal which is based on the magnetic field, to a second support element in a mechanically fixed manner. Step 1330 comprises arranging the first support element and the second support element such that a relative position of the first support element and the second support element relative to each other is variable. The method is executed such that the sensor signal indicates the relative position of the support elements among one another. An order of steps 1310, 1320 and 1330 may thus be as desired. It may be of advantage to perform arranging the support elements relative to one another in the last one of the steps mentioned, for example by exposing or releasing or etching. This does not exclude subsequent steps. Before that, independently of each other since present on two different support substrates, the magnetic means can be connected to the first support element and the sensor means be connected to the second support element. Alternatively, the first support element may process for example by means of surface micromechanics on the second one and only after that realize the magnets in the first support element. Releasing the first support element may be performed by etching from a sacrificial layer. One or more steps may be performed in a common process step.

Thus, the method may be performed such that connecting the permanent-magnetic means comprises the following steps: producing a recess in a region of the support element 12₁; filling a plurality of magnetic or magnetizable microparticles into the recess; and solidifying the number of magnetic or magnetizable microparticles by means of atomic layer deposition. Optionally, magnetization of magnetizable microparticles can be performed after that.

The number of the micromagnets and/or sensor elements in the previously described embodiments is selected merely exemplarily. Any other numbers of permanent-magnetic elements and/or sensor elements and/or reference magnet sources and/or reference sensor elements may be chosen.

When compared to capacitive and piezoresistive position detection, the embodiments illustrated allow monitoring much greater travel distances within the smallest space. Complex trajectories can be monitored using one and the same measuring arrangement. No special electrical connections to the movable microstructure are required, magnetic position detection can work in a contactless manner and is decoupled from driving. No additional forces are to be applied. The powder-based micromagnets described can very easily be integrated in a microstructure. By using reference elements, integrated on the same MEMS device, measuring errors as are exemplarily caused by changes in temperature or electromagnetic stray fields, can be compensated.

Among other things, embodiments can be used for magnetic position detection for monitoring MEMS scanners or micromirrors, for MEMS aperture plates having microlenses and other optical elements, for movable microstructures with radiation sources and detectors, for movable structures in MEMS devices which serve for producing, regulating or monitoring fluidic currents (pumps, valves, mass flux sensors, flow regulators and the like and/or movable microstructures located in an encapsulated volume or system).

Potential embodiments may also be described as follows:
An arrangement comprising a micromechanical structure movable relative to a rigid support element, comprising
   an arrangement of one or more micromagnets integrated in the movable micromechanical structure,
   and an arrangement of one or more magnetic field sensors on the rigid support element,
so that a change in position or movement of the micromechanical structure in space causes a change in the output signals of the magnetic field sensors which unambiguously correlates with this change in position or movement.
The movable micromechanical structure can
   be spring-connected to the support element,
   or else be movable freely.
The movable micromechanical structure can comprise one or more advantageous directions of movement or changes in position. These may be predetermined
   by spring elements which connect the movable micromechanical structure to the support substrate,
   by an axis of rotation around which the micromechanical structure can rotate,
   by limitation surfaces on which the micromechanical structure can move. The movable micromechanical structure can rest on a surface, for example due to gravity, but can slide freely within that plane,
   by limitation edges along which the micromechanical structure can move on a surface.
The distance between the movable micromechanical structure and the rigid support element in the rest state advantageously is between 50 μm and 2000 μm and particularly advantageously between 100 μm and 500 μm.
The edge length of an individual micromagnet advantageously is between 20 μm and 2000 μm and advantageously between 50 μm and 1000 μm.
The distance between the micromagnets advantageously is between 50 μm and 3000 μm and particularly advantageously between 100 μm and 1000 μm.
The number and position of micromagnets on the movable micromechanical structure can match with the number and position of the magnetic field sensors on the support element in a mirror-symmetrical manner. However, the arrangements can also differ in the number of elements and positions thereof.
Micromagnets and magnetic field sensors can be opposed in pairs. However, several magnetic field sensors can also be associated to a micromagnet or one magnetic field sensor be associated to several micromagnets.
Advantageously, but not exclusively, adjacent micromagnets on the movable micromechanical structure are spaced apart from one another such that the stray field of a micromagnet does not influence any of the magnetic field sensors associated to other micromagnets.
A reference magnetic field sensor is placed on the support element such that it is located outside the stray field of the micromagnets on the movable micromechanical structure.
A reference micromagnet, which is integrated in the support element, is arranged opposite the reference magnet field sensor. The reference micromagnet is fixed, i.e. its position relative to the reference magnet field sensor does not change during the movement of the micromechanical structure.
Any magnetic field sensors can be used, like Hall, AMR; GMR, MAGFET, for example. In the case of an array, the sensors can be placed on the support element as individual chips. In particular in the case of smaller distances between the individual sensors, however, integration thereof in a circuit on a chip (ASIC) manufactured by means of well-known semiconductor processes is of advantage.
The micromagnets are produced by agglomeration of lose powder of a magnetic material, with a size in the range of micrometers, by means of atomic layer deposition (ALD).

Although some aspects have been described in connection with a device, it is to be understood that these aspects also represent a description of the corresponding method so that a block or element of a device is to be understood also as a corresponding method step or feature of a method step. In analogy, aspects described in connection with or as a method step, also represent a description of a corresponding block or detail or feature of a corresponding device.

While this invention has been described in terms of several embodiments, there are alterations, permutations, and equivalents which will be apparent to others skilled in the art and which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

### REFERENCES

[1] X. Liu et al., “A MEMS stage for 3-axis nanopositioning”, J. Micromech. Microeng. 17, 2007
[2] A. Hung et al., “An electrostatically driven 2D micro-scanning mirror with capacitive sensing for projection display”, Sensors and Actuators, A 222, 2015
[3] S. Lani et al., “2D MEMS scanner integrating a position feedback”, MATEC, Web of Conferences 32, 01001, 2015
[4] B. Park et al., “Lorentz force based resonant MEMS magnetic-field sensor with optical readout”, Sensors and Actuators A, 241, 2016
[5] X. Cheng et al., “Integrated optoelectronic position sensor for scanning micro-mirrors”, Sensors, 18, 2018
[6] operating instructions SCDplus Märzhäuser, as of: Jun. 11, 2009 Firmware v7.08
[7] UNI LEEDS Wang Design methodology for magnetic field-based soft tri-axis tactile sensors 2017
[8] Z.-H. Xu et. al., “Grooved multi-pole magnetic gratings for high-resolution positioning systems”, Japanese Journal of Applied Physics 54, 2015
[9] C. Coutier et al., “A new magnetically actuated switch for precise position detection”, Proc. IEEE Transducers Conf., Denver, Colo., USA, 2009
[10] M. Nakano et al., “Nd—Fe—B Film magnets with thickness above 100 μm deposited on Si substrates”, Transactions on Magnetics, Vol. 51, No. 11, 2015
[11] E. S. Leland et al., “A MEMS AC current sensor for residential and commercial electricity end-use monitoring”, J. Micromech. Microeng., 19, 2009
[12] N. Jackson et al., “Integration of thick-film permanent magnets for MEMS applications”, J. Microelectromech. Sys., Vol. 25, No. 4, 2016
[13] T. Lisec et al., “A Novel fabrication technique for MEMS based on agglomeration of powder by ALD”, J. Microelectromech. Sys., Vol. 26, No. 5, 2017
[14] Patent specification EP 2670880 B1, “Verfahren zum Erzeugen einer dreidimensionalen Struktur sowie dreidimensionale Struktur” (Method for Producing a Three-Dimensional Structure, and Three-Dimensional Structure)
[15] Published document DE 102016215616 A1, “Verfahren zum Herstellen einer magnetischen Struktur” (Method for Producing a Magnetic Structure)

1. A microsystem comprising:
a first support element and a second support element, wherein a relative position of the first support element and the second support element relative to each other is variable;
a permanent-magnetic unit connected to the first support element in a mechanically fixed manner and configured to generate a magnetic field;
a sensor unit connected to the second support element in a mechanically fixed manner and configured to detect the magnetic field and to provide a sensor signal which is based on the magnetic field;
wherein the sensor signal indicates the relative position of the support elements relative to each other.

2. The microsystem in accordance with claim 1, wherein the permanent-magnetic unit comprises at least one permanent-magnetic element comprising a plurality of particles connected among one another to form a fixed three-dimensional structure by means of a coating.

3. The microsystem in accordance with claim 1, wherein the permanent-magnetic unit comprises at least one permanent-magnetic element comprising a plurality of particles connected among one another to form a fixed three-dimensional structure by means of atomic layer deposition.

4. The microsystem in accordance with claim 1, wherein the permanent-magnetic unit comprises at least one permanent-magnetic element structurally integrated in the first support element.

5. The microsystem in accordance with claim 1, wherein the first support material comprises a semiconductor material, glass material or ceramic material, and the permanent-magnetic element is arranged in a recess of the first support element.

6. The microsystem in accordance with claim 1, wherein the sensor unit comprises at least one sensor element configured to provide a measuring signal.

7. The microsystem in accordance with claim 1, wherein the permanent-magnetic unit comprises a plurality of permanent-magnetic elements which are arranged at a distance to one another such that a detection of the magnetic field of a permanent-magnetic element at the position of a sensor element is influenced by the fields of adjacent permanent-magnetic elements at most to an insignificant extent.

8. The microsystem in accordance with claim 7, wherein an amplitude of the magnetic field of a first permanent-magnetic element of the plurality of permanent-magnetic elements is at most 10% when compared to an amplitude of the magnetic field of a second permanent-magnetic element of the plurality of permanent-magnetic elements, at the position of a sensor element.

9. The microsystem in accordance with claim 7, wherein the distance relates to a pair with a first and a second permanent-magnetic element of the plurality of permanent-magnetic elements and is at least 50 μm for each pair of permanent-magnetic elements; or at least double a lateral dimension a of the first or second permanent-magnetic element along a direction between the first permanent-magnetic element and the second permanent-magnetic element.

10. The microsystem in accordance with claim 7, wherein adjacent permanent-magnetic elements comprise a mutually different magnetic field orientation.

11. The microsystem in accordance with claim 7, wherein at least a part of the permanent-magnetic elements, relative to sensor elements of the sensor unit, is arranged in a plane of the change of the relative position.

12. The microsystem in accordance with claim 7, wherein the change of the relative position is in a plane, wherein at least a part of the permanent-magnetic elements, relative to sensor elements of the sensor unit, is arranged perpendicularly to the plane.

13. The microsystem in accordance with claim 1, wherein the permanent-magnetic unit comprises a number of at least one permanent-magnetic element for generating a magnetic field associated to the permanent-magnetic element; wherein the sensor unit comprises a corresponding number of sensor elements, wherein exactly one sensor element is associated unambiguously to each permanent-magnetic element of the number of permanent-magnetic elements.

14. The microsystem in accordance with claim 1, wherein the permanent-magnetic unit comprises a plurality of permanent-magnetic elements for generating magnetic fields each associated to the permanent-magnetic elements; wherein the sensor unit comprises a corresponding plurality of sensor elements, wherein exactly one sensor element is associated unambiguously to each permanent-magnetic element of the plurality of permanent-magnetic elements.

15. The microsystem in accordance with claim 13, wherein the permanent-magnetic elements are arranged to be opposite the sensor elements in a mirror-symmetrical manner, in a rest position of the microsystem.

16. The microsystem in accordance with claim 1, wherein the permanent-magnetic unit comprises a number of at least one permanent-magnetic element for generating a magnetic field associated to the permanent-magnetic element; wherein the sensor unit comprises a number of sensor elements, wherein at least a first and a second sensor element are associated to each permanent-magnetic element of the number of permanent-magnetic elements, the sensor unit being configured to provide the sensor signal based on an at least differential evaluation of the magnetic field by a measurement at least with the first sensor element and the second sensor element.

17. The microsystem in accordance with claim 1, wherein the permanent-magnetic unit comprises a first permanent-magnetic element for generating a first magnetic field associated to the first permanent-magnetic element and a second permanent-magnetic element for generating a second magnetic field associated to the second permanent-magnetic element; the sensor unit comprising a sensor element associated to the first permanent-magnetic element and the second permanent-magnetic element and configured to detect overlapping of the first magnetic field and the second magnetic field.

18. The microsystem in accordance with claim 1, wherein the sensor unit comprises at least one sensor element, wherein each sensor element is configured to provide an associated measuring signal, the sensor unit being configured to correct disturbing influences on the at least one sensor element at least partly.

19. The microsystem in accordance with claim 18, wherein the sensor unit comprises a reference sensor element configured to detect a reference magnetic field and provide a reference signal, the sensor unit being configured to adjust the measuring signal or the sensor signal using the reference signal to correct the disturbing influences at least partly.

20. The microsystem in accordance with claim 19, wherein the reference magnetic field is an environmental magnetic field of the microsystem.

21. The microsystem in accordance with claim 19, wherein the sensor unit comprises a reference magnetic source configured to generate the reference magnetic field.

22. The microsystem in accordance with claim 21, wherein a relative position between the reference magnetic source and the reference sensor element is fixed.

23. The microsystem in accordance with claim 19, wherein the reference signal is essentially uninfluenced by a change in the relative position.

24. The microsystem in accordance with claim 1, wherein the permanent-magnetic unit comprises at least one permanent-magnetic element, the permanent-magnetic element comprising a first translatory dimension perpendicularly to a thickness direction z and a second, perpendicular translatory dimension, wherein the first translatory and/or second translatory dimension a comprise a value of at least 20 μm and at most 2000 μm.

25. The microsystem in accordance with claim 1, wherein the first support element and the second support element, in a rest position of the microsystem, comprise a distance of at least 10 μm and at most 2000 μm.

26. The microsystem in accordance with claim 1, wherein the first support element is shiftable relatively in a translatory manner relative to the second support element along at least one axis and/or is tiltable relatively to the second support element.

27. The microsystem in accordance with claim 1, wherein the sensor signal unambiguously indicates the relative position of the support elements among one another.

28. The microsystem in accordance with claim 1, wherein the sensor unit comprises at least one sensor element implemented as a Hall sensor, AMR sensor, GMR sensor or MAGFET.

29. The microsystem in accordance with claim 1, wherein the sensor unit comprises at least one sensor element and the sensor element and an evaluating circuit of the sensor unit form an application-specific integrated circuit (ASIC).

30. The microsystem in accordance with claim 1, wherein the first support element is a movable support element and the second support element comprises a substrate so that the sensor signal indicates a position of the movable support element relative to the substrate.

31. The microsystem in accordance with claim 1, wherein the first support element is connected to the second support element via at least one spring element.

32. The microsystem in accordance with claim 31, wherein the at least one spring element presets an advantageous direction of movement for changing the relative position.

33. The microsystem in accordance with claim 1, wherein the first support element or the second support element is formed as a plate element.

34. The microsystem in accordance with claim 33, wherein the plate element is a mirror.

35. The microsystem in accordance with claim 1, wherein a direction of a change of the relative position is based on:
at least an orientation of a spring element between the first support element and the second support element; or
at least an axis of rotation for allowing rotation of the first support element or the second support element; or
at least a limitation surface or limitation edge along which a movement of the first support element and/or the second support element is preset.

36. The microsystem in accordance with claim 1, formed as a scanner, electric switch, optical switch, valve or pump.

37. A method for producing a microsystem, comprising:
connecting a permanent-magnetic unit configured to generate a magnetic field, to the first support element in a mechanically fixed manner;
connecting a sensor unit configured to detect the magnetic field and provide a sensor signal which is based on the magnetic field, to the second support element in a mechanically fixed manner;
arranging a first support element and a second support element such that a relative position of the first support element and of the second support element among each other is variable;
so that the sensor signal indicates the relative position of the support elements among one another.

38. The method in accordance with claim 37, wherein connecting the permanent-magnetic unit comprises:
producing a recess in a region of the first support element;
filling a plurality of magnetic or magnetizable microparticles into the recess; and
solidifying the plurality of magnetic or magnetizable microparticles by means of atomic layer deposition.
